(19) United States
(12) Patent Application Publication
(10) Pub. No.: US 2024/0071811 A1
(43) Pub. Date: Feb. 29, 2024

(54) STACKED FET SUBSTRATE CONTACT

(71) Applicant: International Business Machines Corporation, Armonk, NY (US)

(72) Inventors: Su Chen Fan, Cohoes, NY (US); Jay William Strane, Warwick, NY (US); Gen Tsutsui, Glenmont, NY (US); Stuart Sieg, Albany, NY (US)

(21) Appl. No.: 17/822,173

(22) Filed: Aug. 25, 2022

(51) Int. Cl. H01L 21/762; H01L 21/8238; H01L 25/065; H01L 29/06; H01L 29/786

(52) U.S. Cl. CPC H01L 21/76235; H01L 21/823807; H01L 25/0657; H01L 29/0653; H01L 29/78696

(57) ABSTRACT

A stacked field effect transistor (FET) device. The device includes an opening in a shallow trench isolation (STI) region on a substrate. The device also includes an epitaxy region located on the substrate at a bottom portion of STI region in the opening. The device further includes a substrate contact that directly contacts the epitaxy region.

### BACKGROUND

The present disclosure relates to complementary metal oxide semiconductor (CMOS) structures and methods of forming the same. More particularly, the present disclosure provides a method of forming a substrate contact for a stacked field effect transistor (FET).

CMOS technology can be used to form integrated circuits (ICs), useful in various applications including but not limited to microprocessors, microcontrollers, logic circuits, static random access memory (RAM), etc. CMOS FETs are employed in almost every electronic circuit application such as signal processing, computing, and wireless communications.

### SUMMARY

According to some embodiments of the disclosure, there is provided a stacked field effect transistor (FET) device. The device includes an opening in a shallow trench isolation (STI) region on a substrate. The device also includes an epitaxy region located on the substrate at a bottom portion of STI region in the opening. The device further includes a substrate contact that directly contacts the epitaxy region.

According to some embodiments of the disclosure, there is provided a stacked field effect transistor (FET) device. The device includes an opening in a shallow trench isolation (STI) region on a substrate. The device also includes two types of epitaxy regions, wherein one of the two types of epitaxy regions is located in the opening at a bottom portion of the STI region of the substrate. The device further includes a first substrate contact to directly contact the one type of epitaxy region located at the bottom portion of the STI region.

According to some embodiments of the disclosure, there is provided a method of constructing a stacked field effect transistor (FET). The method includes: forming an opening in a shallow trench isolation (STI) region on a substrate; forming two types of epitaxy regions on the substrate, wherein one of the two types of epitaxy regions is located on a same type of a well implant at the opening and is located at a bottom portion of the STI region; and forming a first contact to directly contact the one type of epitaxy region located at the bottom portion of the STI region.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 is a cross-sectional view of a step in fabrication of a semiconductor structure including a stacked field effect transistor (FET) formed over a substrate, in accordance with an embodiment of the present disclosure;

FIG. 2 is a cross-sectional views of a subsequent step to the step shown in FIG. 1 in fabrication of a semiconductor structure including a stacked FET;

FIG. 3 is a cross-sectional views of a subsequent step to the step shown in FIG. 2 in fabrication of a semiconductor structure including a stacked FET;

FIG. 4 is a cross-sectional views of a subsequent step to the step shown in FIG. 3 in fabrication of a semiconductor structure including a stacked FET;

FIG. 5 is a cross-sectional views of a subsequent step to the step shown in FIG. 4 in fabrication of a semiconductor structure including a stacked FET;

FIG. 6 is a cross-sectional views of a subsequent step to the step shown in FIG. 5 in fabrication of a semiconductor structure including a stacked FET;

FIG. 7 is a cross-sectional views of a subsequent step to the step shown in FIG. 6 in fabrication of a semiconductor structure including a stacked FET;

FIG. 8 is a cross-sectional views of a subsequent step to the step shown in FIG. 7 in fabrication of a semiconductor structure including a stacked FET;

FIG. 9 is a cross-sectional views of a subsequent step to the step shown in FIG. 8 in fabrication of a semiconductor structure including a stacked FET;

FIG. 10 is a cross-sectional views of a subsequent step to the step shown in FIG. 9 in fabrication of a semiconductor structure including a stacked FET;

FIG. 11 is a cross-sectional views of a subsequent step to the step shown in FIG. 10 in fabrication of a semiconductor structure including a stacked FET;

FIG. 12 is a cross-sectional view of a semiconductor structure including a stacked FET formed over a substrate and including a substrate contact, in accordance with an embodiment of the present disclosure; and

FIG. 13 is a flow diagram of a method of constructing a stacked field effect transistor (FET), in accordance with an embodiment of the present disclosure.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure.

### DETAILED DESCRIPTION

Aspects of the present disclosure relate generally to complementary metal oxide semiconductor (CMOS) structures and methods of forming the same. More particularly, the present disclosure provides a method of forming a substrate contact for a stacked field effect transistor (FET). While the present disclosure is not necessarily limited to such applications, various aspects of the disclosure can be appreciated through a discussion of various examples using this context.

Embodiments of the present disclosure relate to an integrated circuit (IC) having a CMOS transistor comprising a p-type field-effect transistor (pFET) and an n-type field-effect transistor (nFET). The methods and devices disclosed herein can be employed in manufacturing products using CMOS methods, etc., and they can be employed in manufacturing a variety of different devices, e.g., memory devices, logic devices, application-specific integrated circuits (ASICs), etc. As will be further appreciated by those skilled in the art, the disclosure can be employed in forming IC products using planar transistor devices or a variety of so-called three-dimensional (3D) devices, such as finFETs. The disclosure applies to all devices, including finFETs, nanowires, nanosheets (NS s) and vertical transport field effect transistors (VTFETs), for example.

In conventional field effect transistor (FET) manufacture, including finFETs and nanosheet (NS) FETs, an N-type FET (nFET) and a P-type FET (pFET), are located in the same plane. A hardmask can be used during conventional FET manufacture in order to grow the P+ epi on a P-well for a substrate contact. In stacked FinFETs and stacked NS FETs, an nFET can be located on a care device and a pFET can be located above the nFET, providing a “stacked” arrangement. However, it can be challenging to grow the nFET on a care device and a pFET on a substrate contact area (with a middle-of-line (MOL) contact) in the same plane. For stacked FETs, complexity can surround allowing for top device protection in order to be able to grow the P+ epi on the substrate contact area.

In this disclosure, methods and structures are described that include the substrate contact that can be located on a shallow trench isolation (STI) region bottom in a stacked FET. A conventional substrate is located above the STI region. Substrate contacts in stacked FETs are usually larger ring features located outside a care macro. The P+ epi can be boron (B)-doped SiGe, Si or SiGe epitaxy. The other contact is the standard double contact—top source/drain (S/D) and bottom S/D/contacts—for stacked FETs.

Examples of semiconductor materials that can be used in forming such NS structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

One feature and advantage of the disclosed structures and processes is a benefit of having substrate contact controls. The substrate contact described herein can allow for leakage through the substrate. As a result, the leakage is not allowed to electrically “float.” The substrate contact allows one end to be grounded for overflow current flow to ground. Another feature of advantage of the disclosed structures and processes is the location of the substrate contact formed on a STI bottom can be easily detectable by top-down and cross-sectioning, for example.

The terms “epitaxially,” “epitaxy,” “epi,” etc., herein carry their customary usage: meaning the single crystal lattice structure carries across an interface. Typically, a single crystal material forms a platform onto which another single crystal material, with matching crystalline characteristics, can be deposited by one of several techniques known in the art. Such techniques are, for instance, molecular beam epitaxy (MBE), or various types of chemical vapor deposition (CVD).

It is to be understood that the present disclosure will be described in terms of a given illustrative architecture; however, other architectures, structures, substrate materials and process features and steps/blocks can be varied within the scope of the present disclosure. It should be noted that certain features cannot be shown in all figures for the sake of clarity. This is not intended to be interpreted as a limitation of any particular embodiment, or illustration, or scope of the claims.

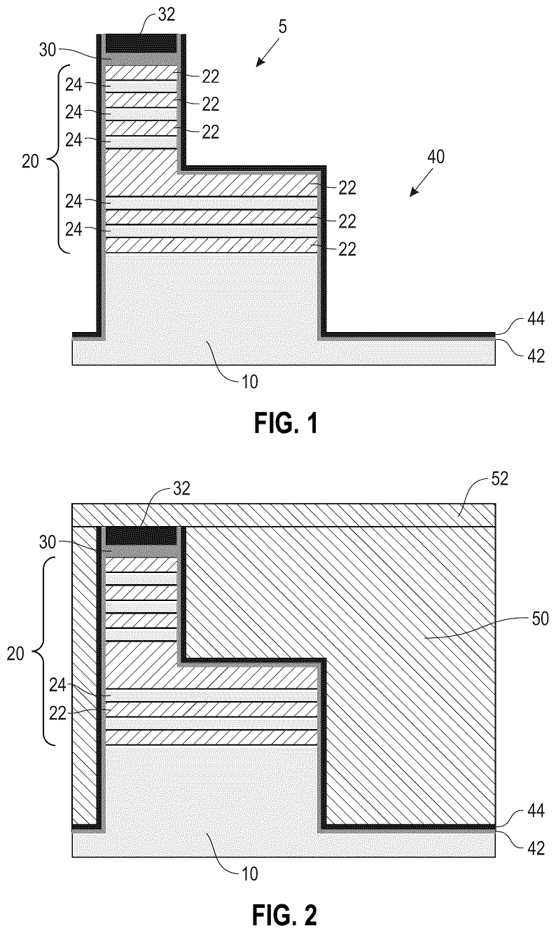

FIG. 1 is a cross-sectional view of a step in a fabrication of a semiconductor structure 5 including a stacked FET formed over a substrate, in accordance with an embodiment of the present disclosure. CMOS process flow starts with blanket P-well ion implantation, which was already completed prior to the step being shown in FIG. 1. Processes, such as conventional or stacked FET active area (AA) reactive-ion etching (RIE) to etch out an STI region, were also already completed prior to the step being shown in FIG. 1. These processes are known by those of skill in the art and are not described in detail herein.

In FIG. 1, and in various example embodiments, a semiconductor structure 5 includes a nanosheet (NS) stack 20 that can be formed over a substrate 10 and can include alternating layers of several semiconductor layers. In one example, a first semiconductor layer 22 is formed over the substrate 10. The first semiconductor layer 22 can be, e.g., silicon germanium (SiGe) with a high concentration of germanium (Ge). In one example, the Ge content can be about 60%. One skilled in the art can contemplate higher concentrations of Ge. This first semiconductor layer 22 can be referred to as a bottom first semiconductor layer 22. The NS stack 20 includes alternating layers of the first semiconductor layer 22 and a second semiconductor layer 24. The second semiconductor layer 24 can be, e.g., silicon (Si). After the NS stack 20 of alternating first and second semiconductor layers 22, 24 are formed over the first semiconductor layer 22, another semiconductor layer 22 (top semiconductor layer 22) can be formed over the NS stack 20 of alternating first and second semiconductor layers 22, 24. Subsequently, a second stack (not shown) of alternating second and third semiconductor layers 24, 26 can be formed over the top first semiconductor layer 22, etc.

In one or more embodiments, the substrate 10 can be a semiconductor or an insulator with an active surface semiconductor layer. The substrate 10 can be crystalline, semi-crystalline, microcrystalline, or amorphous. The substrate 10 can be essentially (e.g., except for contaminants) a single element (e.g., Si), primarily (e.g., with doping) of a single element, for example, Si or Ge, or the substrate 10 can include a compound, for example, aluminum oxide (Al₂O₃), silicon dioxide (SiO₂), gallium arsenide (GaAs), silicon carbide (SiC), or SiGe. The substrate 10 can also have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). The substrate 10 can also have other layers forming the substrate 10, including high-k oxides and/or nitrides. In one or more embodiments, the substrate 10 can be a silicon wafer. In an embodiment, the substrate 10 can be a single crystal silicon wafer.

Referring to, e.g., the NS stack 20, the alternating semiconductor layers 22, 24 can be deposited by any appropriate mechanism. It is specifically contemplated that the semiconductor layers 22, 24 can be epitaxially grown from one another, but alternate deposition processes, such as CVD, physical vapor deposition (PVD), atomic layer deposition (ALD), or gas cluster ion beam (GCIB) deposition, are also contemplated.

In FIG. 1, on top of the NS stack 20, there can be a layer of SiO₂ 30. Above or on top of the SiO₂ layer 30, a hardmask 32 can be deposited. The hardmask 32 can include any of one or more of silicon nitride (SiN), silicon carbon nitride (SiCN), silicon boron nitride (SiBN), and/or silicon boron oxynitride (SiBON), among other materials. The hardmask 32 can be an oxide, for example, a silicon oxide hardmask. The hardmask 32 can be patterned by any suitable patterning techniques, including but not limited to, lithography followed by etching, sidewall image transfer (SIT), self-aligned double patterning (SADP), self-aligned multiple patterning (SAMP), self-aligned quadruple patterning (SAQP), or any suitable combination of those techniques.

FIG. 1 includes an STI region 40 that can be formed by etching a trench in doped bottom S/D regions (not shown) utilizing a conventional dry etching process such as RIE or plasma etching. More than one trench can be present. The STI region 40 is shown, in FIG. 1, and is lined with two layers (making up an STI liner). The two layers include a first layer 42 of SiO₂ and a second, outer layer 44 of SiN are deposited in the STI region 40, etc., as shown. Other suitable materials for the two layers are also contemplated, however.

FIG. 2 is a cross-sectional view of a subsequent step to the step shown in FIG. 1 in the fabrication of the semiconductor structure 5 consistent with some embodiments. As shown an organic planarization layer (OPL) 50 is deposited within recesses and over the second, outer layer 44. A photoresist layer 52 is also shown deposited on top of the OPL 50.

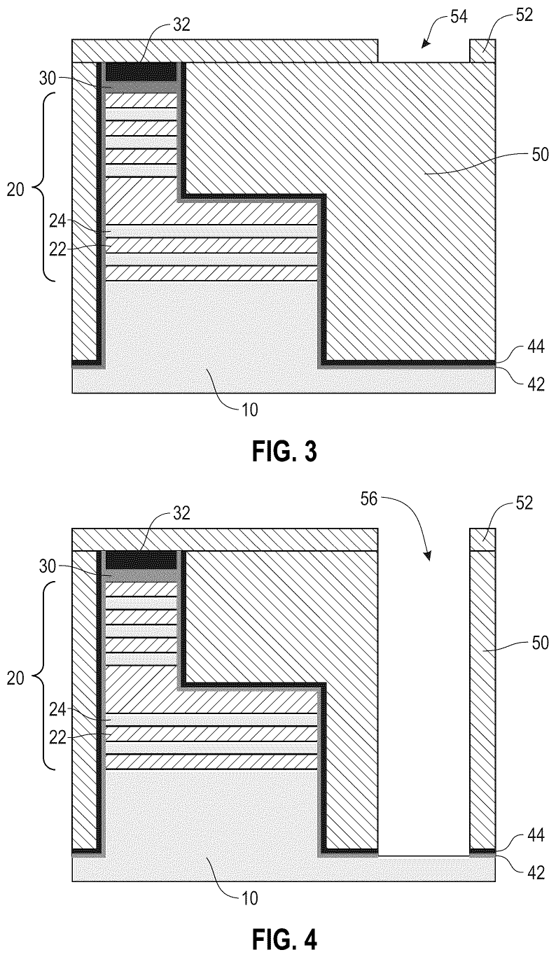

FIG. 3 is a cross-sectional view of a subsequent step to the step shown in FIG. 2 in the fabrication of the semiconductor structure 5 consistent with some embodiments. The figure shows the structure 5 after lithography has been performed to expose an opening 54 in photoresist layer 52.

Next, in FIG. 4, a subsequent step to FIG. 3 is shown, consistent with some embodiments. The figure shows the structure 5 after RIE has been performed to etch through at least a portion of the OPL 50 and at least a portion of both the first layer 42 and the second, outer layer 44 all the way down to the substrate 10, which forms a channel-like opening 56.

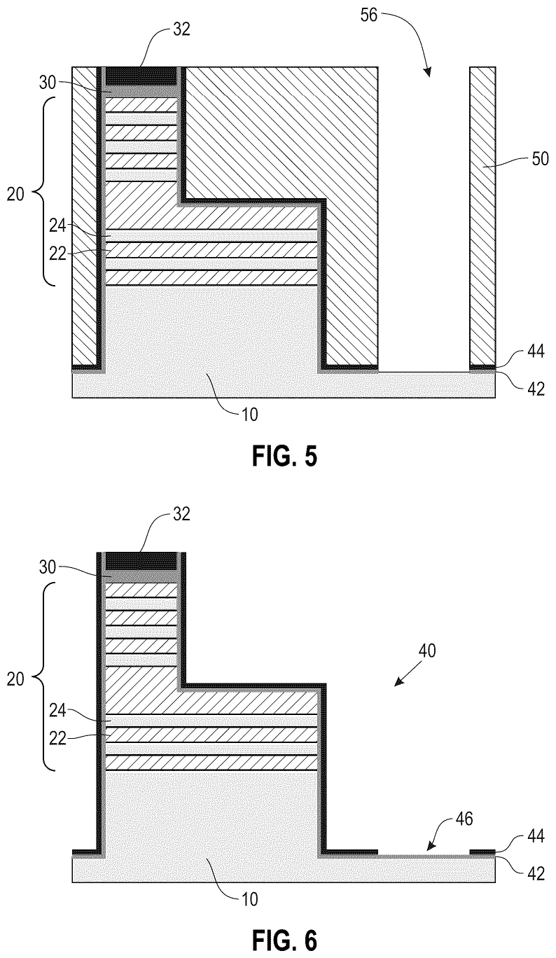

FIG. 5 shows a next step after FIG. 4 consistent with some embodiments. The figure shows that the photoresist layer 52 is removed, which can be made of a suitable organic material, for example. The photoresist layer 52 can be removed, for example, using a dry etch process, although other suitable processes are also contemplated.

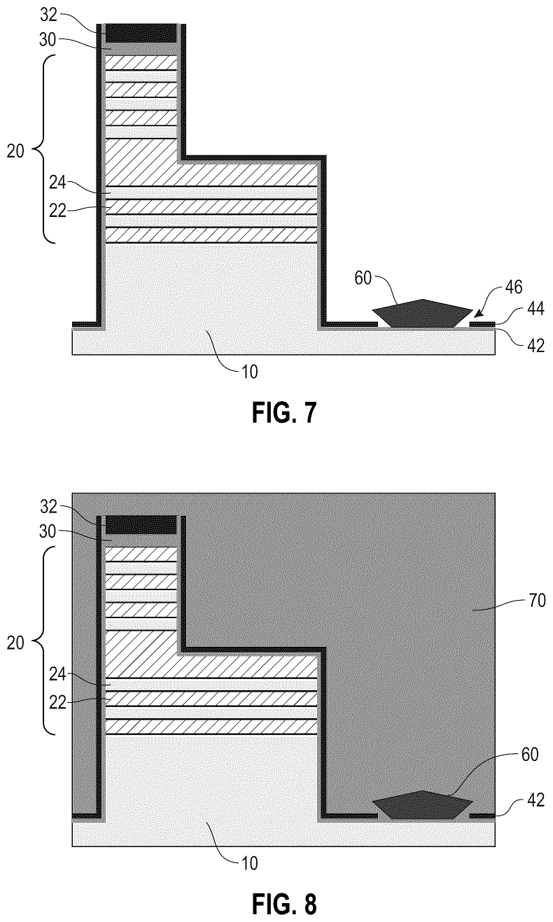

FIG. 6 a next step on the structure 5 with the OPL 50 removed, consistent with some embodiments. The OPL 50 can be removed using a dry etch process with carbon and fluoride chemistry, although other suitable processes are also contemplated. The two layers 42, 44 (both together making up the STI liner) at the bottom of previous opening 56 are also removed, which can allow for epi growth. Only areas where there is no silicon (e.g., an open area 46) are areas where P+ epi (which can be Si or SiGe, for example) will grow during a selective growth process. The P+ epi 60 can be grown using Si epitaxy doped with boron, germanium and/or gallium, for example, although other suitable methods are also contemplated. FIG. 7 shows P+ epi 60 grown on the open area 46 consistent with some embodiments. The P+ epi 60 can be B-doped SiGe, Si or SiGe epitaxy. Although the P+ epi 60 is shown, an N+ epi can alternatively be grown in open area 46.

FIG. 8 next shows that all previously unfilled areas include a SiO₂ filling 70, consistent with some embodiments. The areas can be filled using blanket SiO₂ deposition, which is followed by CVD. Other suitable deposition processes can be used to fill areas including the STI region 40 with SiO₂ or with another like STI dielectric material. The STI dielectric material can optionally be densified after deposition.

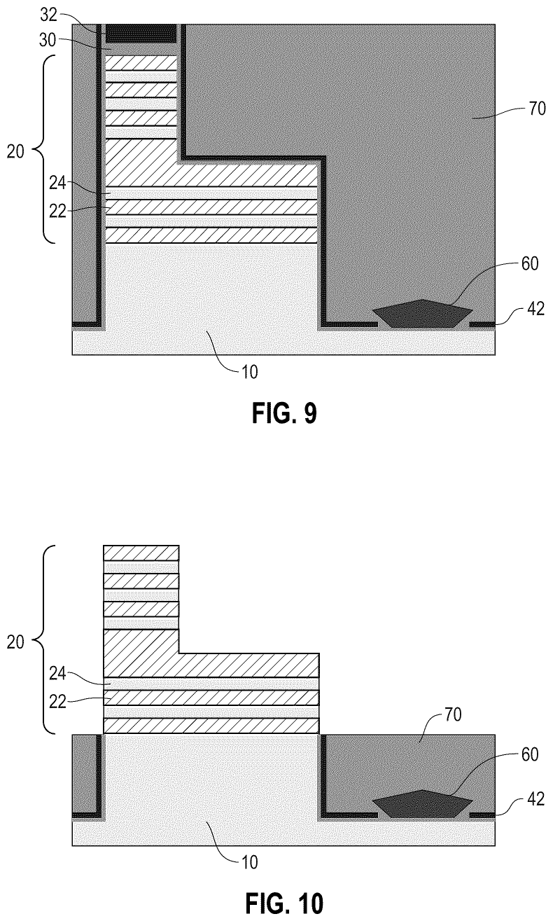

FIG. 9 shows the semiconductor structure 5 after a conventional planarization process such as chemical-mechanical polishing (CMP) has been performed, consistent with some embodiments. The CMP process provides a planar structure to the SiO₂ filling 70 down to the level of the hardmask 32.

Next, FIG. 10 shows the structure 5 after “NS reveal” (or oxide recess) has been performed, consistent with some embodiments. Recessing the SiO₂ filling 70 is done to reveal the NS stack 20. NS reveal can be done, for example, using wet or dry etch to etch oxide with high selective to nitride and/or Si, although other suitable processes are also contemplated.

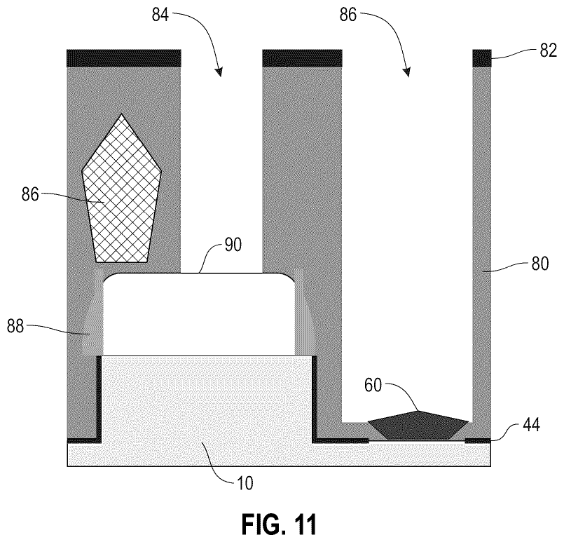

Between FIGS. 10 and 11, there are a series of steps performed to arrive at the structure 5 of FIG. 11, consistent with some embodiments. U.S. Patent Application entitled “Bottom Contact for Stacked GAA FET,” having file number U.S. Ser. No. 17/522,015, and filed on Nov. 9, 2021, describes the steps of forming a bottom contact for a stacked FET and is incorporated herein by reference in full. The steps described in the reference can be used with the present disclosure to arrive at the structure 5 in FIG. 11 from that of FIG. 10.

In order to form the structure 5 of FIG. 11, consistent with some embodiments, a dielectric material layer 80 is deposited followed by CMP. A SiN hardmask 82 can be deposited on top of the dielectric layer 80. Lithography and then RIE can be used to etch and open first and second areas 84, 86 into the dielectric layer 80, as shown. The P+ epi 60 is not in the same plane as an N+ epi 86. The N+ epi 86 can be formed of SiGe, for example. Below the N+ epi 86 is a layer of SiP 90. Surrounding the SiP layer 90 is a layer of SiBCN 88. The substrate contact, or P+ epi 60 can be formed of Si, SiGe or SiP.

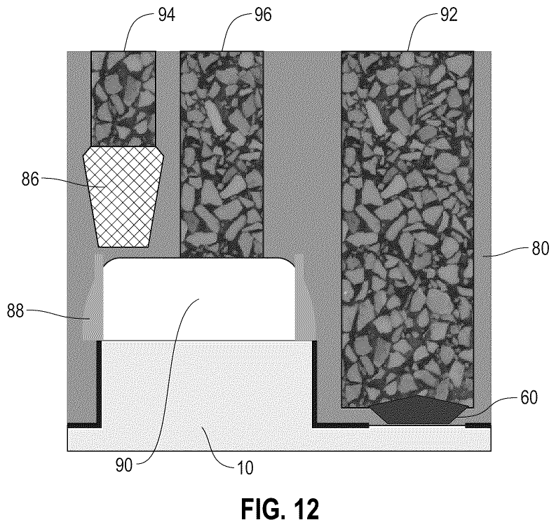

FIG. 12 shows the structure of FIG. 11 after a single metallization process has been performed, consistent with some embodiments. MOL metallization is performed using a metal such as cobalt, tungsten, or ruthenium, for example. As a result, the metal fills the openings, resulting in a top S/D gate contact 94, and a bottom S/D gate contact 96. In addition, the substrate contact area 86 of FIG. 11 is filled with the metal to form a substrate contact 92. CMP can be used following the single metallization process. The substrate contact 92, as shown, lands on the P+ epi 60 at the STI bottom 100. The epi grown on the STI bottom 100, however, can be either P+ or N+. The STI liner (including both 42, 44) at the STI bottom 100 is shown opened to allow for the epi growth. A single metallization process is used to form the substrate contact 92, and both the S/D gate contacts 94, 96.

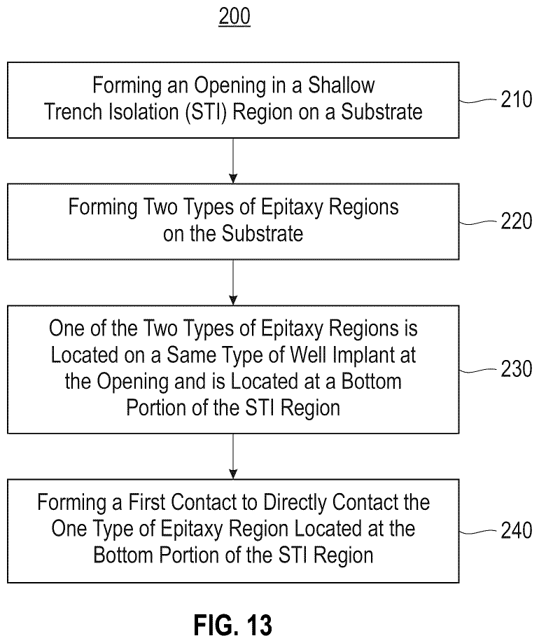

FIG. 13 is a flow diagram of a method 200 of constructing a stacked FET, in accordance with an embodiment of the present disclosure. One process operation in the method 200 is forming an opening 46 in a shallow trench isolation (STI) region 40 on a substrate 10 (operation indicated as 210). An additional process operation is forming two (2) types of epitaxy regions 60, 86 on the substrate 10 (operation indicated as 220). One of the two types of epitaxy regions 60, 86 is located on a same type of a well implant at the opening 46 and is located at the STI bottom 100 of the STI region 40 (operation indicated as 230). Yet another process operation is forming a first contact 92 to directly contact the one type of P+ epi 60 located at the bottom portion 100 of the STI region 40 (operation indicated as 240). Other process operations in method 200 are also contemplated by the present disclosure, such as, for example, described above with regard to FIGS. 1-12.

For purposes of this disclosure, reference will be made to an illustrative process flow wherein for forming a single CMOS transistor device (“CMOS device”). Of course, the disclosure herein should not be considered to be limited to the illustrative examples depicted and described herein. With reference to the attached figures, various illustrative embodiments of the methods and devices disclosed herein will now be described in more detail.

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

As used in this application and in the claims, the singular forms “a,” “an,” and “the” include the plural forms unless the context clearly dictates otherwise. Additionally, the term “includes” means “comprises.”

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

1. A stacked field effect transistor (FET) device comprising:
an opening in a shallow trench isolation (STI) region on a substrate;
an epitaxy region located on the substrate at a bottom portion of STI region in the opening; and
a substrate contact that directly contacts the epitaxy region.

2. The device of claim 1, wherein the epitaxy region is grown on a well implant having a same type as the epitaxy region.

3. The device of claim 1, wherein the epitaxy region is selected from the group consisting of an n-type epitaxial region and a p-type epitaxial region.

4. The device of claim 1, further comprising:
at least one additional contact, wherein the substrate contact and the at least one additional contact include a same metallic material.

5. A stacked field effect transistor (FET) device comprising:
an opening in a shallow trench isolation (STI) region on a substrate;
two types of epitaxy regions, wherein one of the two types of epitaxy regions is located in the opening at a bottom portion of the STI region of the substrate; and
a first substrate contact to directly contact the one type of epitaxy region located at the bottom portion of the STI region.

6. The device of claim 5, wherein the one of the two types of epitaxy regions is located on a same type of a well implant.

7. The device of claim 5, wherein the epitaxy regions are selected from the group consisting of an n-type epitaxial region and a p-type epitaxial region.

8. The device of claim 5, further comprising:
at least one additional contact, wherein the first substrate contact and the at least one additional contact include a same metallic material.

9. A method of constructing a stacked field effect transistor (FET), the method comprising:
forming an opening in a shallow trench isolation (STI) region on a substrate;
forming two types of epitaxy regions on the substrate, wherein one of the two types of epitaxy regions is located on a same type of a well implant at the opening and is located at a bottom portion of the STI region; and
forming a first contact to directly contact the one type of epitaxy region located at the bottom portion of the STI region.

10. The method of claim 9, wherein the forming the opening step includes:
performing lithography followed by reactive ion etching (RIE) in order to open the STI region.

11. The method of claim 9, wherein the forming the first contact step includes:
performing lithography followed by reactive ion etching (RIE) to pattern the first contact.

12. The method of claim 9, further comprising:
forming at least one additional contact.

13. The method of claim 12, wherein the forming the first contact step and the forming at least one additional contact step both include using a single metallization process to form all of the contacts of the stacked FET.

14. The method of claim 9, further comprising:
prior to the opening step, etching out the STI region in the substrate.

15. The method of claim 14, further comprising:
after the etching step, forming a nanosheet (NS) stack over a portion of the substrate that includes alternating layers of semiconductor material.

16. The method of claim 15, further comprising:
after the forming the nanosheet step, depositing a first layer of SiO₂ and a second, outer layer of SiN over the nanosheet stack and in the STI region.

17. The method of claim 16, further comprising:
after the depositing the first a first layer of SiO₂ and a second, outer layer of SiN, depositing an organic planarization layer within recesses and over the second, outer layer of SiN, and depositing a photoresist layer on top of the OPL.

18. The method of claim 17, wherein the forming the opening step includes:
performing lithography to expose an opening in the photoresist layer followed by reactive ion etching (RIE) in order to open the STI region in the organic planarization layer.

19. The method of claim 18, further comprising:
after the forming the opening step, removing the photoresist layer and the OPL.

20. The method of claim 9, wherein the two types of epitaxy regions include n-type and p-type epitaxial regions.
